(19) United States
(12) Patent Application Publication
(10) Pub. No.: US 2021/0167324 A1
(43) Pub. Date: Jun. 3, 2021

(54) OPTOELECTRONIC DEVICE AND PROCESS FOR MANUFACTURING SAME

(71) Applicant: ISORG, Limoges CEDEX 3 (FR)

(72) Inventors: Benjamin BOUTHINON, GRENOBLE (FR); Pierre MULLER, GRENOBLE (FR); David GUILLERMARD, GRENOBLE (FR)

(21) Appl. No.: 15/734,180

(22) PCT Filed: Jun. 3, 2019
(86) PCT No.: PCT/FR2019/051305

§ 371 Date: Dec. 1, 2020

(30) Foreign Application Priority Data
Jun. 4, 2018 (FR) 1800561

(51) Int. Cl. H01L 51/52; H01L 27/30; H01L 51/56; H01L 25/04; H01L 25/16

(52) U.S. Cl. CPC H01L 51/5253; H01L 27/307; H01L 25/167; H01L 51/56; H01L 25/048; H01L 51/5246

(57) ABSTRACT

An optoelectronic device includes a substrate, an array of optoelectronic components covering the substrate, first conductive tracks coupled to the optoelectronic components, an adhesive layer covering a portion of the array, and a coating in contact with the adhesive layer, the coating including a periphery. The device further includes a second track reflecting a radiation at a wavelength in the range 335 nm to 10.6 μm and extending aligned with the periphery along a given direction between the first conductive tracks and the coating.

The present patent application claims the priority benefit of French patent application FR18/00561, which is herein incorporated by reference.

### BACKGROUND

The present disclosure generally concerns optoelectronic devices and methods of manufacturing the same and, more particularly, devices comprising a display screen and/or an image sensor.

### DISCUSSION OF THE RELATED ART

Many computers, touch pads, cell phones, smart watches, are equipped with an image sensor.

FIG. 1 partially and schematically shows an image sensor 10. Image sensor 10 comprises an array 11 of detection elements 12, called optical array hereafter. Detection elements 12 may be arranged in rows and in columns. Each detection element 12 comprises a photodetector 14, for example, a photodiode, and a selection element 16, for example, a transistor having its source or drain coupled to a first electrode of photodiode 14, for example, the cathode. Image sensor 10 comprises a selection circuit 18 comprising, for each row, a conductive track 20 coupled to the gates of selection transistors 16. Image sensor 10 further comprises a readout circuit 22 comprising, for example, for each column, a conductive track 24 coupled to the source or to the drain of column selection transistors 16. Further, the second electrodes of photodiodes 14, for example, the anodes, may be coupled by conductive tracks 26 to a source 28 of a reference potential.

It is known to form detection elements 12 at least partly made of organic materials. Optical array 11 may then be formed separately on a substrate and selection circuit 18, readout circuit 22, and the source of potential 28 may correspond to external circuits which are connected to optical array 11. Optical array 11 generally comprises a stack of layers covered with a coating particularly protecting organic photodiodes 14 against water and the oxygen contained in the air. The coating may correspond to a film which is attached to the optical array via an adhesive layer. A film cutting step is then provided after the bonding of the film to the optical array, particularly to expose contact pads of optical array 11 intended to be connected to selection circuit 18, to readout circuit 22, and to potential source 28. The cutting step may be carried out by means of a laser.

A disadvantage of such a manufacturing method is that the setting of the laser is difficult, whereby the laser cutting step may cause an unwanted deterioration of the conductive tracks 22, 24, 26 located on the path of the laser beam. Further, when the substrate is made of plastic, it may be absorbing for the wavelengths of the laser so that the laser cutting step may cause an unwanted deterioration of the substrate on the path of the laser beam.

### SUMMARY

An object of an embodiment is to overcome all or part of the disadvantages of the previously-described optoelectronic devices and of their manufacturing methods.

Another object of an embodiment is for the optoelectronic device manufacturing method to comprise a cutting step, particularly a laser cutting step.

Another object of an embodiment is for the optoelectronic device to comprise conductive tracks which are not deteriorated.

Another object of an embodiment is for the optoelectronic device to comprise a substrate which is not deteriorated.

Another object of an embodiment is to provide an optoelectronic device comprising a display screen and/or an image sensor.

Another object of an embodiment is for the image sensor to be at least partly made of organic semiconductor materials.

Another object of an embodiment is for all or part of the optoelectronic device to be formed by successive depositions of layers by printing techniques, for example, by inkjet, by heliography, by silk-screening, by flexography, or by coating.

Thus, an embodiment provides an optoelectronic device comprising a substrate, an array of optoelectronic components covering the substrate, first conductive tracks coupled to the optoelectronic components, an adhesive layer covering a portion of the array, and a coating in contact with the adhesive layer, the coating comprising a periphery, the device further comprising a second track reflecting and/or absorbing a radiation at a wavelength in the range from 335 nm to 10.6 μm and extending, aligned with the periphery along a given direction, between the first conductive tracks and the coating.

According to an embodiment, the second track is selected from the group comprising:

a metal or a metal alloy, for example, silver (Ag), gold (Au), lead (Pb), palladium (Pd), copper (Cu), nickel (Ni), tungsten (W), molybdenum (Mo), aluminum (Al), or chromium (Cr), or an alloy of magnesium and silver (MgAg);

carbon, silver, and copper nanowires;

graphene;

colored or black resin, for example, colored or black SU-8 resin; and

a mixture of at least two of these materials.

According to an embodiment, the device comprises a first electrically-insulating layer and, for each optoelectronic component, an electrode in contact with the optoelectronic component, resting on the first insulating layer and in contact with the first insulating layer, the second track resting on the first insulating layer and in contact with the first insulating layer.

According to an embodiment, the second track is made of the same material as the electrodes.

According to an embodiment, the device comprises a second electrically-insulating layer, and for each optoelectronic component, a field-effect transistor and third conductive tracks coupling the transistor to the optoelectronic component, resting on the second insulating layer and in contact with the second insulating layer, the second track being made of the same material as the third tracks, resting on the second insulating layer and in contact with the second insulating layer.

According to an embodiment, the second track is interposed between the adhesive layer and the coating.

According to an embodiment, the optoelectronic components comprise organic photodetectors.

According to an embodiment, the optoelectronic components comprise organic light-emitting components.

An embodiment provides a method of manufacturing the optoelectronic device such as previously defined.

According to an embodiment, the method comprises the steps of:

forming the array of optoelectronic components covering the substrate and the first conductive tracks coupled to the optoelectronic components;

covering the portion of the array with the adhesive layer;

applying a film in contact with the adhesive layer; and

cutting the film by using a laser beam extending along a given direction to obtain the coating,

the method further comprising forming the second track reflecting and/or absorbing the laser beam and extending aligned with the periphery of the coating along said given direction between the first conductive tracks and the coating.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1, previously described, shows an electric diagram of an example of an image sensor;

FIGS. 2 and 3 respectively are a cross-section view and a top view, partial and simplified, of an example of an optical array of an image sensor;

FIGS. 4A to 4C are partial simplified cross-section views of the structures obtained at successive steps of an embodiment of a method of manufacturing the optical array shown in FIGS. 2 and 3;

FIGS. 5 and 6 respectively are a cross-section view and a top view, partial and simplified, of an embodiment of an optical array; and

FIGS. 7 to 9 are partial simplified cross-section views of embodiments of an optical array.

### DETAILED DESCRIPTION

The same elements have been designated with the same reference numerals in the different drawings. The same elements have been designated with the same reference numerals in the different drawings. In particular, the operation of a display screen and of an image sensor has not been detailed, the described embodiments being compatible with usual display screens and image sensors. Further, the other components of the optoelectronic device integrating a display screen and/or an image sensor have not been detailed either, the described embodiments being compatible with the other usual components of display screen and/or image sensor optoelectronic devices.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms ““in the order of” and “substantially”, this means within 10%, preferably within 5%. Further, when reference is made to terms qualifying the absolute position, such as terms “top”, “bottom”, etc., or the relative position, such as terms “above”, “under”, “upper”, “lower”, etc., unless specified otherwise, reference is made to the orientation of the drawings.

The expression active region of an optoelectronic component, particularly of a light-emitting component or of a photodetector, designates the region from which most of the electromagnetic radiation supplied by the optoelectronic component is emitted or from which most of the electromagnetic radiation received by the optoelectronic component is captured. In the following description, an optoelectronic component is called organic when the active region of the optoelectronic component is mainly, preferably totally, made of at least one organic material or of a mixture of organic materials. Further, an element said to be reflective for a radiation is an element having its reflection factor for the radiation greater than 80%, preferably greater than 90%, more preferably greater than 95%, the reflection factor being defined as being the ratio of the flow of the reflected radiation to the flow of the incident radiation.

An embodiment will now be described for an optical array in the case where the optoelectronic components of the optical array are organic photodiodes. It should however be clear the electronic components may correspond to light-emitting components.

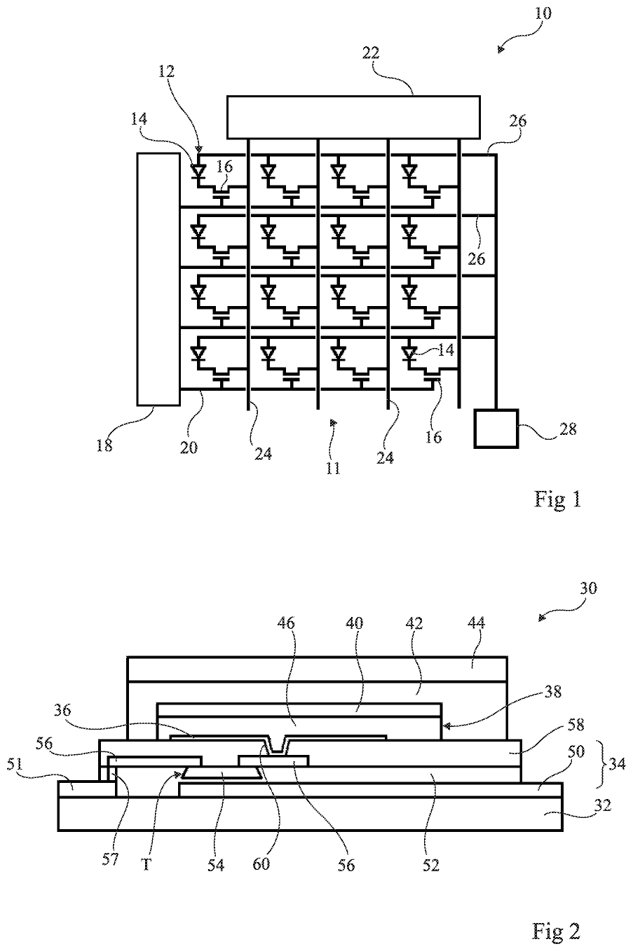

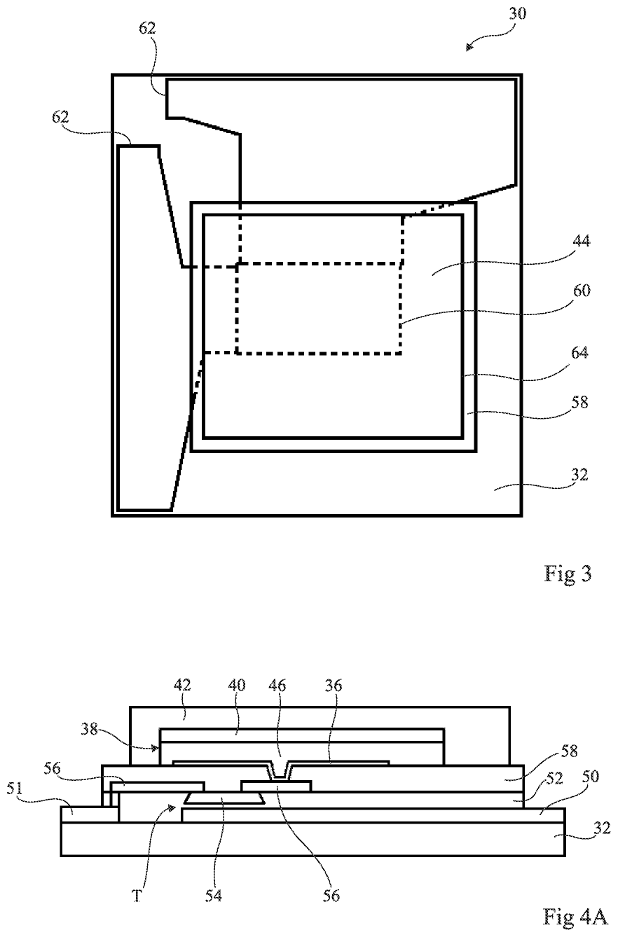

FIG. 2 is a partial simplified lateral cross-section view of an example of an optical array 30 having an electric diagram capable of corresponding to the optical array 11 shown in FIG. 1.

Optical array 30 comprises, from bottom to top in FIG. 2:

a substrate 32;

a stack 34 having thin-film transistors formed therein, a single transistor T being shown in FIG. 2;

electrodes 36, each electrode 36 being coupled to one of transistors T, a single electrode 36 being shown in FIG. 2;

photodetectors 38, for example, organic photodiodes, also called OPD, a single photodiode 38 being shown in FIG. 2, each photodiode 38 being in contact with one of electrodes 36;

an electrode 40 in contact with all organic photodiodes 38;

a layer of an adhesive material 42; and

a coating 44.

According to an embodiment, each photodiode 38 comprises an active region 46, electrodes 36 and 40 being in contact with active region 46. As a variant, each organic photodiode 38 may comprise a first interface layer in contact with one of electrodes 36, active region 46 in contact with the first interface layer, and a second interface layer in contact with active region 46, electrode 40 being in contact with the second interface layer.

According to the present embodiment, stack 34 comprises:

electrically-conductive tracks 50, 51 resting on substrate 32, tracks 50 forming the gate conductors of transistors T and tracks 51 being coupled with the drains or with the sources of transistors T;

a layer 52 of a dielectric material covering tracks 50, 51 and substrate 32 between tracks 50, 51 and forming the gate insulators of transistors T;

active regions 54 resting on dielectric layer 52 opposite gate conductors 50;

electrically-conductive tracks 56 extending on dielectric layer 52, some of these tracks being in contact with active regions 54 and forming the drain and source contacts of transistors T, some of tracks 56 being electrically coupled to tracks 51 via electrically-conductive vias 57 extending through layer 52; and

a layer 58 of a dielectric material covering active regions 54 and electrically-conductive tracks 56, electrodes 36 resting on layer 58 and being connected to some of conductive tracks 56 by conductive vias 60 crossing insulating layer 58 and electrode 40 being connected to some of conductive tracks 51 by conductive vias, not shown in FIG. 2, crossing insulating layers 58 and 52.

As a variant, transistors T may be of high gate type.

When at least one interface layer is present in contact with active region 46, this interface layer may correspond to an electron injection layer or to a hole injection layer. The work function of each interface layer is capable of blocking, collecting, or injecting holes and/or electrons according to whether the interface layer plays the role of a cathode or of an anode. More particularly, when the interface layer plays the role of an anode, it corresponds to a hole injection and electron blocking layer. The work function of the interface layer is then greater than or equal to 4.5 eV, preferably greater than or equal to 5 eV. When the interface layer plays the role of a cathode, it corresponds to an electron injection and hole blocking layer. The work function of the interface layer is then smaller than or equal to 4.5 eV, preferably smaller than or equal to 4.2 eV.

In the present embodiment, electrode 36 or 40 advantageously directly plays the role of an electron injection layer or of a hole injection layer for photodiode 38, and it is not necessary to provide, for photodiode 38, an interface layer in contact with active region 46 and playing the role of an electron injection layer or of a hole injection layer.

Substrate 32 may be a rigid substrate or a flexible substrate. Substrate 32 may have a monolayer structure or correspond to a stack of at least two layers. An example of a rigid substrate comprises a silicon, germanium, or glass substrate. Preferably, substrate 32 is a flexible film. An example of flexible substrate comprises a film of PEN (polyethylene naphthalate), PET (polyethylene terephthalate), PI (polyimide), TAC (cellulose triacetate), COP (cycloolefin copolymer), or PEEK (polyetheretherketone). The thickness of substrate 32 may be in the range from 5 μm to 1,000 μm. According to an embodiment, substrate 32 may have a thickness from 10 μm to 300 μm, preferably from 75 μm to 250 μm, particularly in the order of 125 μm, and may have a flexible behavior, that is, substrate 32 may, under the action of an external force, deform, and particularly bend, without breaking or tearing. Substrate 32 may comprise at least one substantially oxygen- and moisture-tight layer, to protect the organic layers of optical array 30. This may be one or a plurality of layers deposited by an atomic layer deposition (ALD) method, for example, an Al₂O₃ layer.

According to an embodiment, the material forming electrodes 36, 40 is selected from the group comprising:

a transparent conductive oxide (TCO), particularly indium tin oxide (ITO), aluminum zinc oxide (AZO), gallium zinc oxide (GZO), an ITO/Ag/ITO alloy, an ITO/Mo/ITO alloy, a AZO/Ag/AZO alloy, or a ZnO/Ag/ZnO alloy;

a metal or a metal alloy, for example, silver (Ag), gold (Au), lead (Pb), palladium (Pd), copper (Cu), nickel (Ni), tungsten (W), molybdenum (Mo), aluminum (Al), or chromium (Cr), or an alloy of magnesium and silver (MgAg);

carbon, silver, and/or copper nanowires;

graphene; and

a mixture of at least two of these materials.

The material forming electrode 40 may further be selected from the group comprising the PEDOT:PSS polymer, which is a mixture of poly(3,4)-ethylenedioxythiophene and of sodium polystyrene sulfonate, or a polyaniline, tungsten oxide (WO₃), nickel oxide (NiO), vanadium oxide (V₂O₅), or molybdenum oxide (MoO₃).

When optical array 30 is exposed to a light radiation, the latter reaches photodiodes 38 through coating 44, electrode 40, and coating 44 are at least partly transparent to the electromagnetic radiation captured by photodiodes 38. Electrode 40 is for example made of TCO. Electrodes 36 and substrate 32 may then be opaque to the electromagnetic radiation captured by photodiodes 38. When the radiation reaches photodiodes 38 through substrate 32, electrodes 36 and substrate 32 are made of a material at least partly transparent to the electromagnetic radiation captured by photodiodes 38. Electrodes 36 are for example made of TCO. Electrode 40 may then be opaque to the electromagnetic radiation captured by photodiodes 38.

Each insulating layer 52, 58 may have a monolayer or multilayer structure and comprise at least one layer made of silicon nitride (SiN), of silicon oxide (SiO₂), or of a polymer, particularly, a resin.

Layer 42 of adhesive material is transparent or partially transparent to visible light. Layer 42 of adhesive material is preferably substantially air- and water-tight. The material forming layer 42 of adhesive material is selected from the group comprising a polyepoxide or a polyacrylate. Among polyepoxides, the material forming layer 42 of adhesive material may be selected from the group comprising bisphenol A epoxy resins, particularly the diglycidylether of bisphenol A (DGEBA) and the diglycidylethers of bisphenol A and of tetrabromobisphenol A, bisphenol F epoxy resins, novolac epoxy resins, particularly epoxy-phenol-novolacs (EPN) and epoxy-cresol-novolacs (ECN), aliphatic epoxy resins, particularly epoxy resins with glycidyl groups and cycloaliphatic epoxides, glycidyl amine epoxy resins, particularly the glycidyl ethers of methylene dianiline (TGMDA), and a mixture of at least two of these compounds. Among polyacrylates, the material forming layer 42 of adhesive material may be made from monomers comprising acrylic acids, methylmethacrylate, acrylonitrile, methacrylates, methyl acrylate, ethyl acrylate, 2-chloroethyl vinyl ether, 2-ethylhexyl acrylate, hydroxyethyl methacrylate, butyl acrylate, butyl methacrylate, trimethylolpropane triacrylate (TMPTA), or derivatives of these products.

When layer 42 of adhesive material comprises at least one polyepoxide or a polyacrylate, the thickness of layer 42 of adhesive layer 42 is in the range from 1 μm to 50 μm, preferably from 5 μm to 40 μm, particularly in the order of 15 μm.

Coating 44 is a flexible film. An example of flexible film comprises a film of PEN (polyethylene naphthalate), PET (polyethylene terephthalate), PI (polyimide), TAC (cellulose triacetate), COP (cycloolefin copolymer), or PEEK (polyetheretherketone). The thickness of coating 44 may be in the range from 5 μm to 1,000 μm.

According to an embodiment, substrate 32 may have a thickness from 10 μm to 300 μm, preferably from 25 μm to 100 μm, particularly in the order of 50 μm, and may have a flexible behavior, that is, the coating may, under the action of an external force, deform, and particularly bend, without breaking or tearing. Coating 44 may comprise at least one substantially oxygen- and moisture-tight layer to protect the organic layers of optical array 30. Coating 44 may comprise at least one SiN layer, for example, deposited by plasma-enhanced chemical vapor deposition (PECVD) and/or one aluminum oxide layer (Al₂O₃), for example, deposited by ALD.

Active region 46 comprises at least one organic material and may comprise a stack or a mixture of a plurality of organic materials. Active region 46 may comprise a mixture of an electron donor polymer and of an electron acceptor molecule. The functional area of active region 46 is delimited by the overlapping of lower electrode 36 and of upper electrode 40. The currents crossing the functional area of active region 46 may vary from a few femtoamperes to a few microamperes. The thickness of the active region 46 covering lower electrode 36 may be in the range from 50 nm to 5 μm, preferably from 300 nm to 2 μm, for example, in the order of 500 nm.

Active region 46 may comprise small molecules, oligomers, or polymers. These may be organic or inorganic materials. Active layer 46 may comprise an ambipolar semiconductor material, or a mixture of an N-type semiconductor material and of a P-type semiconductor material, for example in the form of stacked layers or of an intimate mixture at a nanometer scale to form a bulk heterojunction.

Example of P-type semiconductor polymers capable of forming active region 42 are poly(3-hexylthiophene) (P3HT), poly[N-9′-heptadecanyl-2,7-carbazole-alt-5,5-(4,7-di-2-thienyl-2′,1′,3′-benzothiadiazole] (PCDTBT), Poly[(4,8-bis-(2-ethylhexyloxy)-benzo[1,2-b;4,5-b′]dithiophene)-2,6-diyl-alt-(4-(2-ethylhexanoyl)-thie-no[3,4-b]thiophene))-2,6-diyl]; 4,5-b′]dithi-ophene)-2,6-diyl-alt-(5,5′-bis(2-thienyl)-4,4,-dinonyl-2,2′-bithiazole)-5′,5″-diyl] ( PBDTTT-C), le poly[2-methoxy-5-(2-ethyl-hexyloxy)-1,4-phenylene-vinylene] (MEH-PPV) or Poly[2,6-(4,4-bis-(2-ethylhexyl)-4H-cyclopenta [2,1-b;3,4-b′]dithiophene)-alt-4,7(2,1,3-benzothiadiazole)] (PCPDTBT).

Examples of N-type semiconductor materials capable of forming active region 42 are fullerenes, particularly C60, [6,6]-phenyl-C₆₁-methyl butanoate ([60]PCBM), [6,6]-phenyl-C₇₁-methyl butanoate ([70]PCBM), perylene diimide, zinc oxide (ZnO), or nanocrystals enabling to form quantum dots.

In the case where an interface layer is present and the interface layer plays the role of an electron injection layer, the material forming the interface layer is selected from the group comprising:

a metal oxide, particularly a titanium oxide or a zinc oxide;

a molecular host/dopant system, particularly the products commercialized by Novaled under trade names NET-5/NDN-1 or NET-8/MDN-26;

a conductive or doped semiconductor polymer, for example, the PEDOT:Tosylate polymer, which is a mixture of poly(3,4)-ethylenedioxythiophene and of tosylate;

a carbonate, for example CsCO3;

a polyelectrolyte, for example, poly[9,9-bis(3′-(N,N-dimethylamino)propyl)-2,7-fluorene-alt-2,7-(9,9-dioctyfluorene)] (PFN), poly[3-(6-trimethylammoniumhexyl] thiophene (P3TMAHT) or poly[9,9-bis(2-ethylhexyl)fluorene]-b-poly[3-(6-trimethylammoniumhexyl] thiophene (PF2/6-b-P3TMAHT);

a polyethyleneimine (PEI) polymer or a polyethyleneimine ethoxylated (PEIE), propoxylated, and/or butoxylated polymer;

MgAg;

tris(8-hydroxyquinoline)aluminum(III) (Alq₃);

2-(4-Biphenylyl)-5-(4-tert-butylphenyl)-1,3,4-oxadiazole (Bu-PBD); and

a mixture of two or more of these materials.

In the case where an interface layer is present and the interface layer plays the role of a hole injection layer, the material forming the interface layer may be selected from the group comprising:

a conductive or doped semiconductor polymer, particularly the materials commercialized under trade names Plexcore OC RG-1100, Plexcore OC RG-1200 by Sigma-Aldrich, PEDOT:PSS;

a molecular host/dopant system, particularly the products commercialized by Novaled under trade names NHT-5/NDP-2 or NHT-18/NDP-9;

a polyelectrolyte, for example, Nafion;

a metal oxide, for example, a molybdenum oxide, a vanadium oxide, ITO, or a nickel oxide;

Bis[(1-naphthyl)-N-phenyl]benzidine (NPB);

triarylamines (TPD); and

a mixture of two or more of these materials.

Preferably, in the case where the interface layer plays the role of a hole injection layer, the material forming the interface layer is a conductive or doped semiconductor polymer.

In the case where the optical array comprises light-emitting components, particularly organic light-emitting diodes, the active region of the light-emitting diode is for example made of a light-emitting material. The light-emitting material may be a polymeric light-emitting material, such as described in the publication entitled “Progress with Light-Emitting Polymers” of M. T. Bernius, M. Inbasekaran, J. O'Brien and W. Wu (Advanced Materials, 2000, Volume 12, Issue 23, pages 1737-1750) or a light-emitting material of low molecular weight such as aluminum trisquinoline, as described in patent U.S. Pat. No. 5,294,869. The light-emitting material may comprise a mixture of a light-emitting material or of a fluorescent dye or may comprise a layered structure of a light-emitting material and of a fluorescent dye. Light-emitting polymers comprise polyfluorene, polybenzothlazole, polytriarylamine, poly (phenylenevinylene), and polythiophene. The preferred light-emitting polymers comprise homopolymers and copolymers of 9,9-di-n-octylfluorene (F8), of N, N-bis (phenyl)-4-sec-butylphenylamine (TFB), of benzothiadiazole (BT), and of 4,4′-N,N′-dicarbazole-biphenyl (CBP) doped with iridium tris(2-phenylpyridine) (Ir(ppy)3). The thickness of active region 46 is in the range from 1 nm to 100 nm.

Conductive tracks 50, 51, 56 may be made of the same material as electrodes 36 or 40. The thickness of conductive tracks 50, 51 may be smaller than 50 μm.

Active regions 54 may be made of polysilicon, particularly low-temperature polycrystalline silicon (LIPS), of amorphous silicon (aSi), of zinc-gallium-indium (IGZO), of polymer, or comprise small molecules used in known fashion for the forming of organic thin film transistors (OTFT).

Each insulating layer 52, 58 may be made of SiN, of SiO₂, or of an organic polymer. Insulating layer 52 may have a thickness in the range from 10 nm to 4 μm and insulating layer 58 may have a thickness in the range from 10 nm to 4 μm.

Optical array 30 may further comprise a polarizing filter, for example arranged on coating 44. Optical array 30 may further comprise color filters opposite photodetectors 38 to obtain a wavelength selection of the radiation reaching photodetectors 38.

FIG. 3 is a partial simplified top view of the optical array 30 shown in FIG. 2. FIG. 3 shows in dotted lines 60 the periphery of the area having photodiodes 38 formed therein and in full lines and dotted lines 62 the peripheries of areas having conductive tracks 50 and 51 formed therein. The periphery 64 of coating 44 has further been shown with a full line. As shown in FIG. 3, a portion of areas 62, shown in full lines, is not covered with coating 44 to allow the connection to conductive tracks 50, 51 of selection circuit 18, of readout circuit 22, and of potential source 28, not shown in FIG. 3.

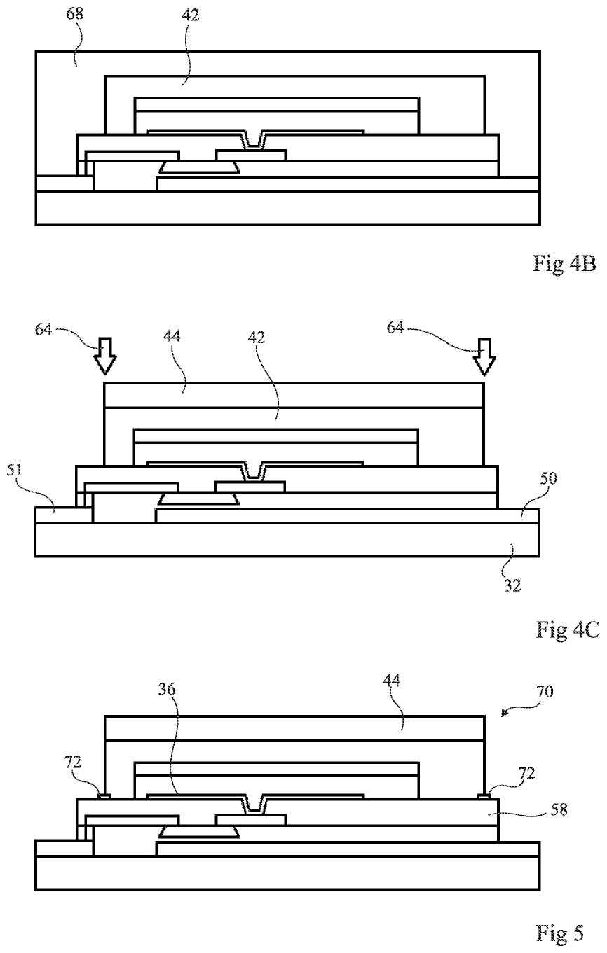

FIGS. 4A to 4C are partial simplified cross-section views of the structures obtained at successive steps of another embodiment of a method of manufacturing the optical array 30.

FIG. 4A shows the structure obtained after the forming of the stack of layers comprising transistors T, electrodes 36, photodetectors 38, electrode 40, and layer 42 of adhesive material.

According to the considered materials, the method of forming the layers of the optical array may correspond to a so-called additive process, for example, by direct printing of the material forming the organic layers at the desired locations, particularly in sol-gel form, for example, by inkjet printing, photogravure, silk-screening, flexography, spray coating, or drop casting. According to the considered materials, the method of forming the layers of the optical array may correspond to a so-called subtractive method, where the material forming the organic layers is deposited all over the structure and where the non-used portions are then removed, for example, by photolithography or laser ablation. According to the considered material, the deposition over the entire structure may be performed, for example, by liquid deposition, by cathode sputtering, or by evaporation. Methods such as spin coating, spray coating, heliography, slot-die coating, blade coating, flexography, or silk-screening, may in particular be used. When the layers are metallic, the metal is for example deposited by evaporation or by cathode sputtering over the entire support and the metal layers are delimited by etching.

Advantageously, at least some of the layers of the optical array may be formed by printing techniques. The materials of the previously-described layers may be deposited in liquid form, for example, in the form of conductive and semiconductor or insulating inks by means of inkjet printers. “Materials in liquid form” here also designates gel materials capable of being deposited by printing techniques. Anneal steps may be provided between the depositions of the different layers, but it is possible for the anneal temperatures not to exceed 150° C., and the deposition and the possible anneals may be carried out at the atmospheric pressure.

FIG. 4B shows the structure obtained after the deposition of a film 68 made of the same material as the desired coating 44. This may be performed by a lamination step during which film 68 is applied against adhesive layer 42, possibly under pressure and with a heating.

FIG. 4C shows the structure obtained after a step of coating of film 68 to form coating 44. The cutting step may be a laser cutting step. As an example, the laser is a CO₂-type continuous laser with a wavelength in the range from 9.4 μm to 10.6 μm. As an example, the power of the laser is in the range from 1 W to 100 W, the displacement speed being in the range from 1 cm/s to 10 m/s. An alternative is to use a continuous nitrogen laser with a 337.1-nm wavelength or a pulsed Yag laser with wavelengths of from 1,050 nm to 1,070 nmn, 1,550 nm, or 2,100 nm. The cutting is preferably performed with a CO₂ laser. The path followed by the laser beam is schematically indicated in FIG. 4C by arrows 64.

The inventors have shown that the laser cutting step may cause a deterioration of conductive tracks 50, 51 by the laser beam, and particularly a local interruption of conductive tracks 50, 51, on the path of the laser. Further, in the case where substrate 32 is made of a plastic material, substrate 32 may absorb the laser beam, which may cause a local deterioration of substrate 32 on the path of the laser.

The inventors have shown that deteriorations due to the laser cutting step may be avoided by providing a track of a material reflecting the laser radiation and/or of a material absorbing the laser radiation on the path of the laser during the cutting step, the track being interposed between the laser beam on the one hand and conductive tracks 50, 51 and substrate 32 on the other hand. Preferably, the width of this track is greater than 500 μm, preferably greater than 1 mm.

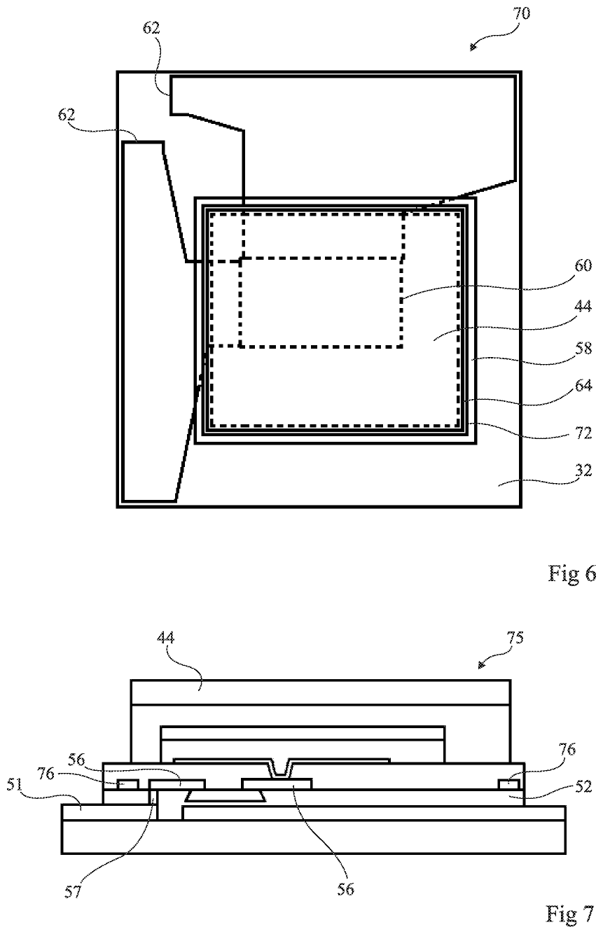

FIGS. 5 and 6 respectively are a cross-section view and a top view, partial and simplified, of an embodiment of an optical array 70 comprising a protection for the cutting step. Optical array 70 comprises all the elements of the optical array 30 shown in FIG. 2 and further comprises at least one reflective track 72 resting on insulating layer 58 on the cutting path of film 68. According to an embodiment, reflective track 72 is an electrically-conductive track formed simultaneously to electrodes 36 and made of the same material as electrodes 36 when electrodes 36 are made of a reflective material.

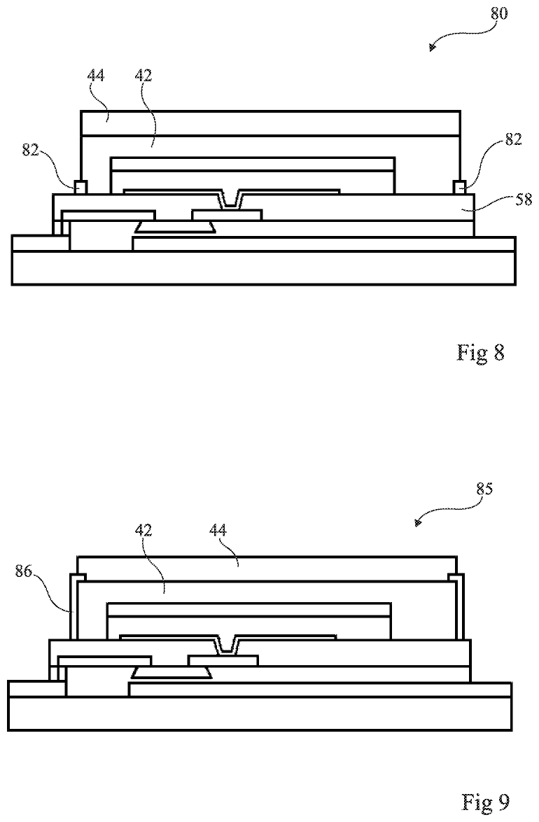

FIG. 7 is a partial simplified cross-section view of an embodiment of an optical array 75 comprising a protection for the cutting step. Optical array 75 comprises all the elements of the optical array 30 shown in FIG. 2 and further comprises a reflective track 76 resting on insulating layer 52 on the cutting path of film 68. According to an embodiment, reflective track 76 is an electrically-conductive track formed simultaneously to tracks 56 and made of the same material as tracks 56.

According to an embodiment, the material forming track 72 or 76 is selected from the group comprising:

a metal or a metal alloy, for example, silver (Ag), gold (Au), lead (Pb), palladium (Pd), copper (Cu), nickel (Ni), tungsten (W), molybdenum (Mo), aluminum (Al), or chromium (Cr), or an alloy of magnesium and silver (MgAg);

an ITO/Mo/ITO stack;

carbon, silver, and/or copper nanowires;

graphene; and

a mixture of at least two of these materials.

The thickness of track 72 or 76 may be in the range from 10 nm to 10 μm.

When track 72, 76 is electrically conductive, it may be coupled, during the operation of the optical array, to a source of a low reference potential, for example, to ground, to the source of potential 28, or to a source of the potential controlling the turning on of transistors T.

FIG. 8 is a partial simplified cross-section view of an embodiment of an optical array 80 comprising a protection for the cutting step. Optical array 80 comprises all the elements of the optical array 30 shown in FIG. 2 and further comprises a track 82 of a material absorbing the radiation of the laser and resting on insulating layer 58 on the cutting path of film 68. Track 82 may be made of colored resin, for example, a colored or black SU-8 resin. In the present embodiment, track 82 is formed on insulating layer 58 before the deposition of adhesive layer 42, for example, according to one of the previously described additive or subtractive method techniques. The thickness of track 82 may be in the range from 100 nm to 50 μm.

FIG. 9 is a partial simplified cross-section view of an embodiment of an optical array 85 comprising a protection for the cutting step. Optical array 85 comprises all the elements of the optical array 30 shown in FIG. 2 and further comprises a track 86 of a material absorbing the radiation of the laser resting on adhesive layer 42 on the cutting path of coating 44. Track may be made of the same material as track 82. In the present embodiment, track 86 is formed on adhesive layer 42 before the application of the film forming coating 44, for example, according to one of the previously described additive or subtractive method techniques.

Various embodiments with different variants have been described hereabove and various variants and modifications will occur to those skilled in the art. It should be noted that those skilled in the art may combine these various embodiments and variants without showing any inventive step. In particular, the optical array may comprise both photodetectors and light-emitting components.

1. An optoelectronic device comprising a substrate, an array of optoelectronic components covering the substrate, first conductive tracks coupled to the optoelectronic components, an adhesive layer covering a portion of the array, and a coating in contact with the adhesive layer, the coating comprising a periphery, the device further comprising a second track reflecting a radiation at a wavelength in the range from 335 nm to 10.6 μm and extending, aligned with the periphery along a given direction, between the first conductive tracks and the coating.

2. The optoelectronic device according to claim 1, wherein the second track is selected from the group comprising:
a metal or a metal alloy, for example, silver (Ag), gold (Au), lead (Pb), palladium (Pd), copper (Cu), nickel (Ni), tungsten (W), molybdenum (Mo), aluminum (Al), or chromium (Cr), or an alloy of magnesium and silver (MgAg);
carbon, silver, and/or copper nanowires;
graphene;
colored or black resin, for example, colored or black SU-8 resin; and
a mixture of at least two of these materials.

3. The optoelectronic device according to claim 1, comprising a first electrically-insulating layer and, for each optoelectronic component, an electrode in contact with the optoelectronic component, resting on the first insulating layer and in contact with the first insulating layer, the second track resting on the first insulating layer and in contact with the first insulating layer.

4. The optoelectronic device according to claim 3, wherein the second track is made of the same material as the electrodes.

5. The optoelectronic device according to claim 1, comprising a second electrically-insulating layer, and for each optoelectronic component, a field-effect transistor and third conductive tracks coupling the transistor to the optoelectronic component, resting on the second insulating layer and in contact with the second insulating layer, the second track being made of the same material as the third tracks, resting on the second insulating layer and in contact with the second insulating layer.

6. The optoelectronic device according to claim 1, wherein the second track is interposed between the adhesive layer and the coating.

7. The optoelectronic device according to claim 1, wherein the optoelectronic components comprise organic photodetectors.

8. The optoelectronic device according to claim 1, wherein the optoelectronic components comprise organic light-emitting diodes.

9. A method of manufacturing the optoelectronic device according to claim 1.

10. The method according to claim 9, comprising the steps of:
forming the array of optoelectronic components covering the substrate and the first conductive tracks coupled to the optoelectronic components;
covering the portion of the array with the adhesive layer;
applying a film in contact with the adhesive layer; and
cutting the film by using a laser beam extending along the given direction to obtain the coating,
the method further comprising forming the second track reflecting the laser beam and extending aligned with the periphery of the coating along said given direction between the first conductive tracks and the coating.
